(19) United States
(12) Patent Application Publication
(10) Pub. No.: US 2003/0183370 A1
(43) Pub. Date: Oct. 2, 2003

(54) Pump type heat radiator

(76) Inventor: Chin-Wen Wang, Ping Jen City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/112,736

(22) Filed: Apr. 2, 2002

(51) Int. Cl. F28F 7/00; H05K 7/20; H01L 23/34

(52) U.S. Cl. 165/80.4; 361/699; 257/714

(57) ABSTRACT

The present invention relates to a pump heat spreader and more particularly, to a cooling system specially used generated when a CPU of a desktop computer operates. The present invention includes an outer ring heat spreader, a plurality of heat-radiating fins inside the outer ring heat spreader, a pump, and a fan. Different from the conventional open-end heat-spreading fins, the present invention provides a closed and concentrated heat-radiating structure to achieve the heat-radiating function of compulsory flow of fluid. Through the special structure of the present invention, heat can be effectively and totally radiated out of the computer in circulatory way and with increased heat-radiating area.

### FIELD OF THE INVENTION

The present invention relates to a pump type heat radiator and, more particularly, to a cooling system specially used when a central processing unit (CPU) of a desktop computer operates. The present invention uses compulsory flow of fluid to enhance the heat-radiating function. Through the special structure of the present invention, heat can be effectively and totally radiated out of the computer in circulatory way and with increased heat-radiating area.

### BACKGROUND OF THE INVENTION

Nowadays, every aspect of lives cannot come off the range of scientific technology. Scientific progress mainly shows in the invention of computer. Especially, the influence of central processing unit (CPU) in the computer has already totally permeated personal life.

Along with quick development of the computer industry, computers have more and more powerful operational capacity, and the operational speeds of CPUs become faster and faster. Moreover, the CPUs give out more and more heat. In order to let the CPUs operate under admissible temperatures, various kinds of heat radiators having increased heat-radiating areas have been proposed to apply to electronic parts giving out more heat like the CPUs.

However, the heat-radiating function of conventional heat-radiating fins can hardly solve the heat-radiating problem of heat source generated when the CPU operates with the operational speed thereof enhanced more and more.

As shown in FIG. 1, in a prior art desktop computer, a plurality of open-end erect heat-radiating fins 2′ are generally used for cooling of a CPU 6 thereof. Heat source generated by the CPU 6 in the computer is spread from a bottom face 1′ to the heat-radiating fins 2′. A fan 4 is also matched to radiate out heat. As shown in FIG. 2, a plurality of heat-radiating fins 2″ are circularly distributed with a central cylinder heat spreader 1″ as the center. A fan 4 is also matched to accomplish the whole heat-radiating function.

However, because the one side of the above heat-radiating fins opposite to the fan is a closed plane, the heat-radiating capacity in limited space is much restrained. Moreover, the prior art open-end heat-radiating fins are solid material, which spreads heat by means of heat conduction. Therefore, the heat-radiating speed is much slower than the speed at which heat is discharged by means of heat convection when the CPU operates. The heat-radiating efficiency thereof is thus not good enough.

Accordingly, the present invention aims to provide a pump type heat radiator to resolve the problems in the prior art.

### SUMMARY OF THE INVENTION

The primary object of the present invention is to provide a pump type heat radiator, which concentratedly radiates out heat in a closed space. In addition to heat conduction between solid structures, heat-radiating effect achieved by compulsory flow of fluid can also be obtained, thereby enhancing the heat-radiating function thereof. Through the special structure of the present invention, heat can be effectively and totally radiated out of the computer in circulatory way and with increased heat-radiating area, thereby enhancing convenience and efficiency of the present invention.

To achieve the above object, the present invention provides a pump type heat radiator, which comprises an outer ring heat spreader having a hollow position therein, a plurality of heat-radiating fins, and a pump. The hollow position is filled with cooling liquid. The heat-radiating fins are situated inside the outer ring heat spreader. The pump is properly connected to the hollow position of the outer ring heat spreader, and can drive the cooling liquid in the hollow position to flow in circulatory way, hence letting heat source be quickly transferred and achieving heat-radiating function of compulsory flow of fluid.

The various objects and advantages of the present invention will be more readily understood from the following detailed description when read in conjunction with the appended drawing, in which:

### BRIEF DESCRIPTION OF THE DRAWINGS

FIG. 1 is a perspective view of heat-radiating subassemblies in the prior art;

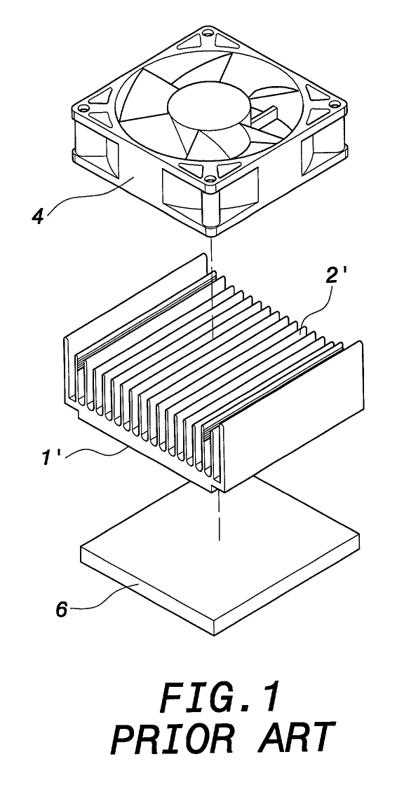

FIG. 2 is a perspective view of another kind of heat-radiating subassemblies in the prior art;

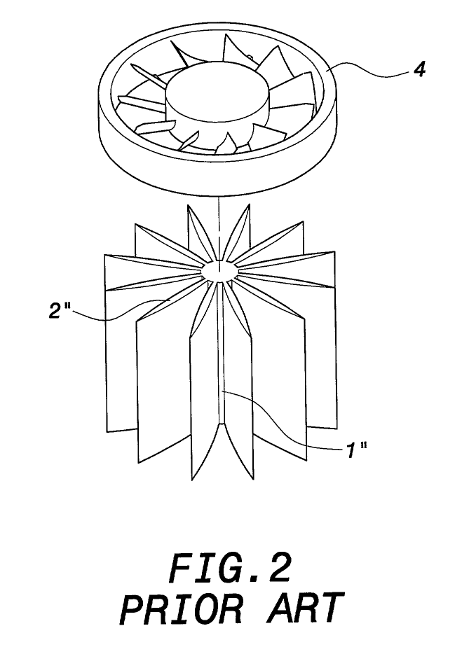

FIG. 3 is a front view according to a first embodiment of the present invention;

FIG. 4 is a side view according to the first embodiment of the present invention;

FIG. 5 is a front view according to a second embodiment of the present invention;

FIG. 6 is a side view according to the second embodiment of the present invention;

FIG. 7 is a front view according to a third embodiment of the present invention; and

FIG. 8 is a side view according to the third embodiment of the present invention.

### DETAILED DESCRIPTION OF THE PREFERRED EMBODIMENTS

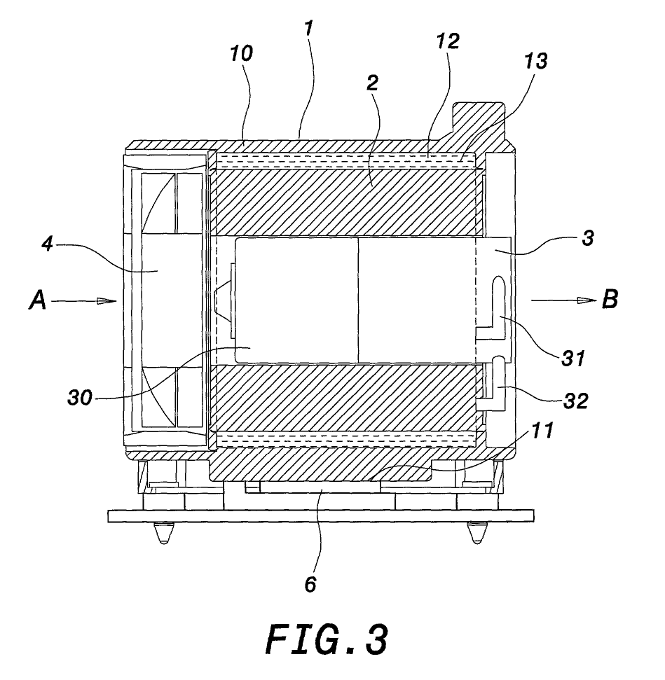

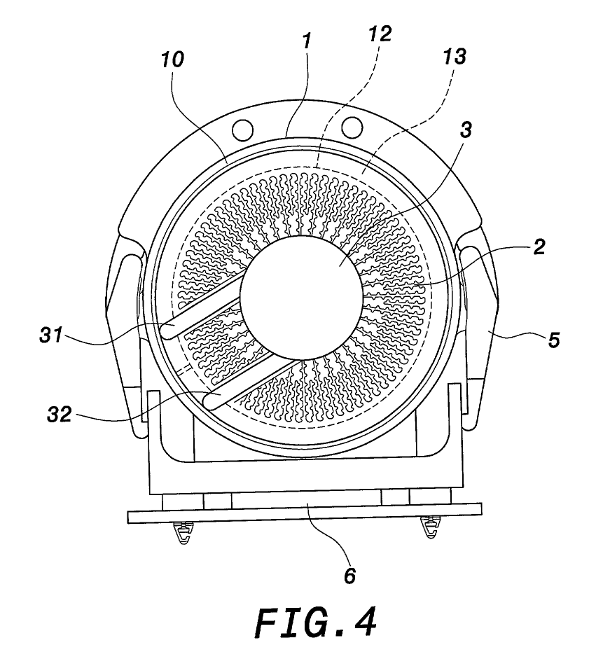

As shown in FIGS. 3 and 4, the present invention provides a pump type heat radiator comprising an outer ring heat spreader 1, a plurality of heat-radiating fins 2, a pump 3, and a fan 4. The pump type heat radiator is placed on a CPU 6. The pump 3 is used to drive cooling liquid to flow for radiating out heat in circulatory way when the CPU 6 operates.

The outer ring heat spreader 1 is made of material of good heat conductance, and comprises a seat bottom face 11 and an annular wall 10. The annular wall 10 is formed of a cylindrical ring. The inner edge of the annular wall 10 has a hollow receiving space, which penetrates to two ends of the outer ring heat spreader 1. A hollow position 12 is annularly disposed in the annular wall 10. The hollow position 12 can be filled with cooling liquid 13 to enhance heat-spreading and cooling functions of the outer ring heat spreader 1.

The heat-radiating fins 2 are situated in the receiving space of the outer ring heat spreader 1. The heat-radiating fins 2 project from the inner wall of the outer ring heat spreader 1, and radially gather together toward the center of the outer ring heat spreader 1. Space for installing the pump 3 is preserved at the center of the heat-radiating fins 2. In this embodiment, the heat-radiating fins 2 are designed in radial form.

The pump 3 can be installed in the heat-radiating fins 2. The pump 3 has a motor 30 to drive it. The pump 3 and the fan 4 can commonly use a motor. The pump 3 is also connected to the hollow position 12 of the outer ring heat spreader 1 via a pipeline 31 and a pipeline 32 so that the pump 3 can drive the cooling liquid 13 in the hollow position 12 to flow in circulatory way.

The fan 4 is disposed at one end of the annular wall 10 of the outer ring heat spreader 1. Airflow is generated through rotation of the fan 4 to assist the heat-radiating fins in radiating out heat. The pump 3 and the fan 4 can separately use a motor each, or can commonly use a motor. That is, the pump 3 and the fan 4 can use a motor with two power-output ends, hence reducing the cost and the installation space of motor. A pump type heat radiator of the present invention is thus formed.

Please refer to FIGS. 3 and 4, the pump type heat radiator of the present invention is disposed on the CPU 6 using an appropriate fastening piece 5. Appropriate heat-spreading pipes (not shown) can also be connected at two ends of the outer ring heat spreader 1. Heat source generated when the CPU 6 operates is conducted to the annular wall 10 via the seat bottom face 11 of the outer ring heat spreader 1. Rotation of the fan 4 generates airflow to assist the heat-radiating fins 2 in radiating out heat. Simultaneously, the pump 3 can drive the cooling liquid 13 in the hollow position 12 to flow in circulatory way so the heat source generated by the CPU 6 can be quickly transferred. Residual heat will spread to the heat-radiating fins 2 by means of circulation similar to heat convection.

Rotation of the fan 4 can further enhance flow of air through the heat-radiating fins 2, hence driving hot air and cold air to generate compulsory flow. Cold air enters from direction A, while hot air flows out in direction B. Compulsory flow of cold and hot air will enhance heat-radiating function. Moreover, through the special structure of the present invention, heat can be effectively and totally radiated out of the computer in circulatory way and with increased heat-radiating area, hence increasing convenience and efficiency of the present invention.

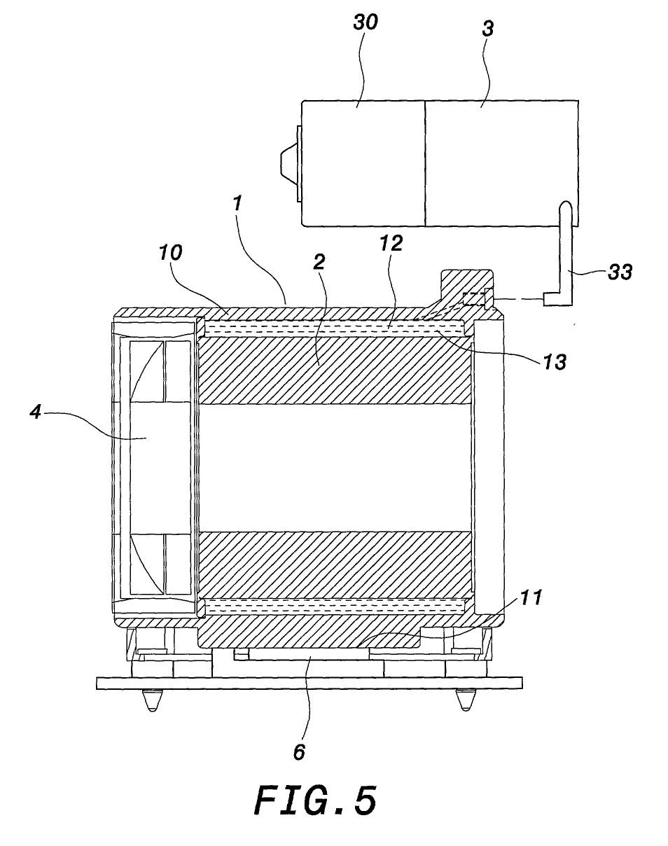

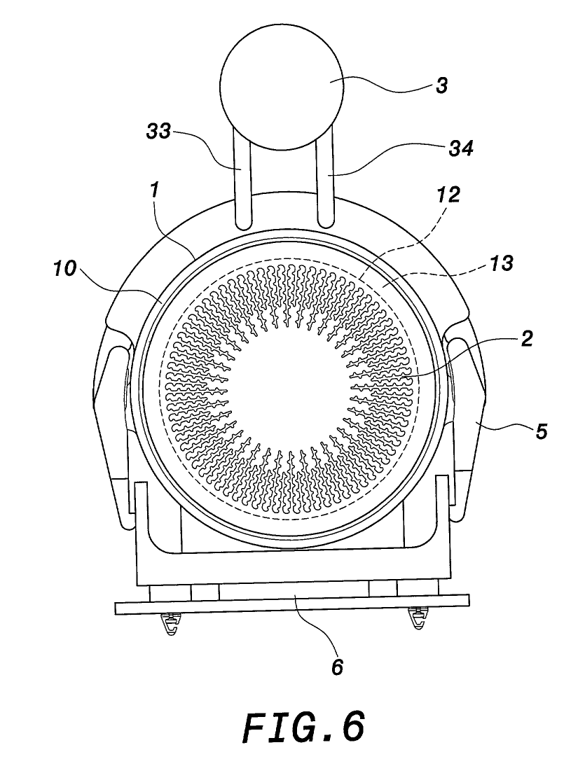

Additionally, as shown in FIGS. 5 and 6, the pump 3 of the present invention can also be installed outside the outer ring heat spreader 1. The pump 3 is connected to the hollow position 12 of the outer ring heat spreader 1 via a pipeline 33 and a pipeline 34 so that the pump 3 can drive the cooling liquid 13 in the hollow position 12 to flow in circulatory way.

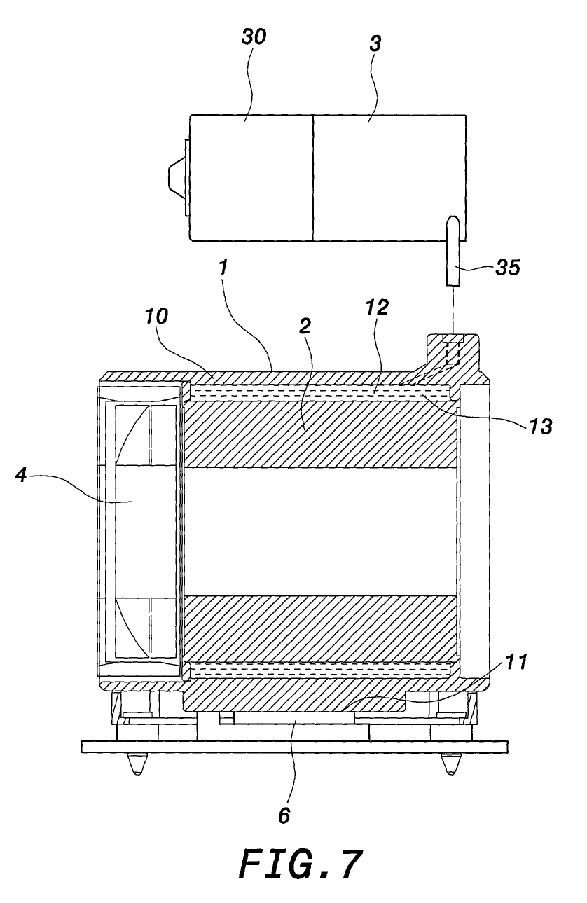

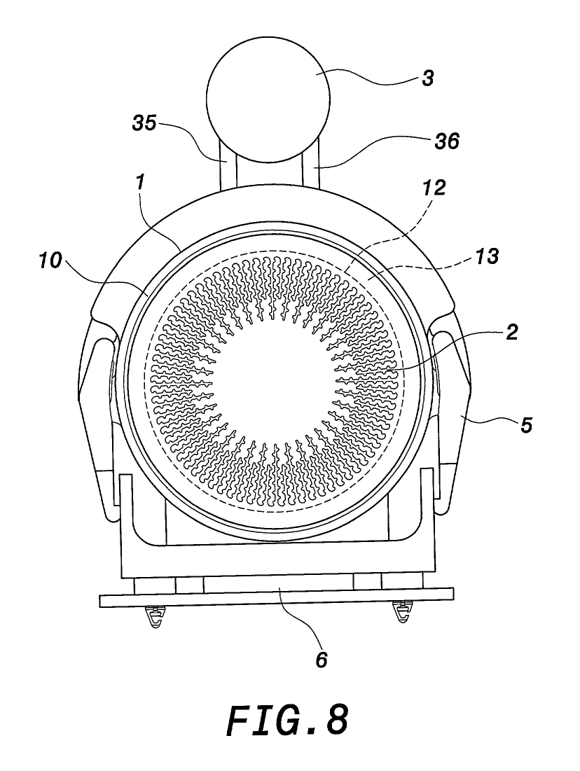

Besides, as shown in FIGS. 7 and 8, the pump 3 of the present invention can also be installed outside the outer ring heat spreader 1. The pump 3 is retained with the hollow position 12 of the outer ring heat spreader 1 via a connector 35 and a connector 36 so that the pump 3 can drive the cooling liquid 13 in the hollow position 12 to flow in circulatory way.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A pump type heat radiator, comprising:
an outer ring heat spreader having a hollow position therein filled with cooling fluid;
a plurality of heat-radiating fins situated inside said outer ring heat spreader; and
a pump properly connected to said hollow position of said outer ring heat spreader, said pump being capable of driving said cooling liquid in said hollow position to flow in circulatory way so heat source can be quickly transferred, thereby achieving heat-radiating function of compulsory flow of fluid.

2. The pump type heat radiator as claimed in claim 1, wherein said outer ring heat spreader comprises a seat bottom face and an annular wall, an inner edge of said annular wall having a hollow receiving space, which penetrates to two ends of said outer ring heat spreader, and said heat-radiating fins are situated in said receiving space of said outer ring heat spreader.

3. The pump type heat radiator as claimed in claim 1, wherein a fan is disposed at one end of said outer ring heat spreader.

4. The pump heat spreader as claimed in claim 3, wherein said pump and said fan are commonly driven by a motor.

5. The pump heat spreader as claimed in claim 1, wherein said heat-radiating fins project from an inner wall of said outer ring heat spreader and radially gather together to a center of said outer ring heat spreader.

6. The pump heat spreader as claimed in claim 1, wherein said pump is installed inside said heat-radiating fins.

7. The pump heat spreader as claimed in claim 1, wherein said pump has a motor to drive it.

8. The pump heat spreader as claimed in claim 1, wherein said pump is installed outside said outer ring heat spreader.

9. The pump heat spreader as claimed in claim 8, wherein said pump is connected to said hollow position of said outer ring heat spreader via pipelines.

10. The pump heat spreader as claimed in claim 8, wherein said pump is retained with said hollow position of said outer ring heat spreader via connectors.
